(19) United States
(12) Patent Application Publication
(10) Pub. No.: US 2024/0171129 A1
(43) Pub. Date: May 23, 2024

(54) CLASS D AMPLIFIER CIRCUIT

(71) Applicant: ROHM CO., LTD., Kyoto-shi (JP)

(72) Inventor: Hideo ARAKI, Kyoto-shi (JP)

(21) Appl. No.: 18/505,195

(22) Filed: Nov. 9, 2023

(30) Foreign Application Priority Data
Nov. 17, 2022 (JP) 2022-184368

(51) Int. Cl. H03F 1/30; H03F 3/217

(52) U.S. Cl. CPC H03F 1/303; H03F 3/2171; H03F 2200/03; H03F 2200/447; H03F 2200/474

(57) ABSTRACT

The present disclosure provides a class D amplifier circuit. The class D amplifier circuit includes: a class D amplifier, including an output section that includes a switching element and outputs an output signal; a current mirror circuit, including a pair of bipolar transistors configured to generate an output current according to a current flowing through the switching element; an element unit, including a resistive component configured to generate a voltage based on the output current of the current mirror circuit; and a comparator, configured to compare the voltage generated by the element unit with a reference voltage. The element unit is configured such that the resistive component compensates for a temperature characteristic of the current flowing through the switching element.

### CROSS REFERENCES TO RELATED APPLICATIONS

The present invention claims priority under 35 U.S.C. § 119 to Japanese Application, 2022-184368, filed on Nov. 17, 2022, the entire contents of which being incorporated herein by reference.

### TECHNICAL FIELD

The present disclosure relates to a class D amplifier circuit.

### BACKGROUND

Class D amplifiers (patent document 1) are conventionally used to drive electroacoustic conversion elements such as speakers.

### PRIOR ART DOCUMENT

### Patent Publication

[Patent document 1]: Japan Patent Publication No. 2018-46431

### BRIEF DESCRIPTION OF THE DRAWINGS

FIG. 1 is a circuit diagram of a class D amplifier circuit according to an embodiment of the present disclosure.

FIG. 2 is a circuit diagram of a reference generation circuit according to an embodiment of the present disclosure.

FIG. 3 is a circuit diagram of a reference current circuit according to the same embodiment.

FIG. 4 is a circuit diagram of a class D amplifier circuit of a comparison technique.

FIG. 5 is a diagram of simulation results of temperature characteristics of short-circuit currents for the class D amplifier circuit in FIG. 1 and the class D amplifier circuit in FIG. 4.

### DETAILED DESCRIPTION OF THE EMBODIMENTS

### (Summary)

A summary of several exemplary embodiments of the disclosure is given below. The summary serves as the preamble of the detailed description to be given shortly and aims at providing fundamental understanding of the embodiments by describing several concepts of one or more embodiments in brief. It should be noted that the summary is not to be construed as limitations to the scope of the application or disclosure. The summary is not a comprehensive summary of all conceivable embodiments, nor does it intend to specify important elements of all embodiments or to define the scope of a part of or all aspects. For the sake of better description, “one embodiment” sometimes refers to one embodiment (an implementation example or a variation example) or multiple embodiments (implementation examples or variation examples) described in the disclosure.

A class D amplifier circuit according to an embodiment includes: a class D amplifier, including an output section that includes a switching element and outputs an output signal; a current mirror circuit, including a pair of bipolar transistors configured to generate an output current according to a current flowing through the switching element; an element unit, including a resistive component configured to generate a voltage based on the output current of the current mirror circuit; and a comparator, configured to compare the voltage generated by the element unit with a reference voltage. The element unit is configured such that the resistive component compensates for a temperature characteristic of the current flowing through the switching element.

According to the configuration above, a temperature change in the current of the switching element can be inhibited by the element unit. Thus, the precision for short-circuit detection of the class D amplifier can be enhanced by utilizing the current.

In one embodiment, the class D amplifier circuit further includes: a reference generation unit including a second element unit having a resistive component when the element unit is set to be a first element unit and configured to generate the reference voltage by passing a current through the second element unit. A sign of a temperature characteristic of the resistive component of the first element unit can be same as a sign of a temperature characteristic of the resistive component of the second element unit. Thus, the precision for short-circuit detection of the class D amplifier can be enhanced by the configuration above.

A slope of the temperature characteristic of the resistive component of the first element unit can be same as a slope of the temperature characteristic of the resistive component of the second element unit. Thus, the precision for short-circuit detection of the class D amplifier can be enhanced by the configuration above.

The second element unit can include a metal-oxide-semiconductor field-effect transistor (MOSFET). The reference generation unit can generate the reference voltage based on a voltage generated by an on-resistance of the MOSFET.

The switching element can include a MOSFET. A sign of a temperature characteristic of the on-resistance of the MOSFET can be same as a sign of a temperature characteristic of a thermal voltage of the bipolar transistor. Thus, the precision for short-circuit detection of the class D amplifier can be enhanced by the configuration above.

A slope of the temperature characteristic of the on-resistance of the MOSFET can be same as a slope of the temperature characteristic of the thermal voltage of the bipolar transistor. Thus, the precision for short-circuit detection of the class D amplifier can be enhanced by the configuration above.

### Embodiments

Details of preferred embodiments of the disclosure are given with the accompanying drawings below. The same or equivalent constituent element in the accompanying drawings is represented by the same denotations, and repeated description is omitted as appropriate. Moreover, the configurations described below are merely examples and are not to be construed as limitations to the disclosure.

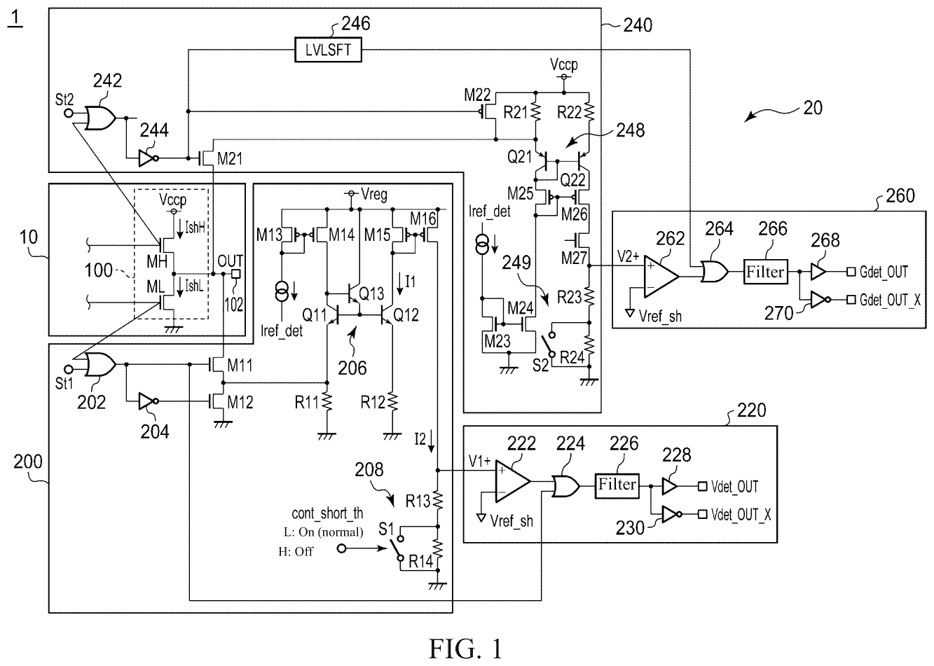

FIG. 1 shows a circuit diagram of a class D amplifier circuit 1 according to an embodiment of the present disclosure. The class D amplifier circuit 1 is utilized for an amplifier for various devices such as speakers. The class D amplifier circuit 1 of this embodiment includes a class D amplifier 10 and a short-circuit detection circuit 20.

The class D amplifier 10 is input with an input signal and generates and outputs a signal corresponding to the input signal. The class D amplifier 10 outputs an output signal from an output terminal 102 by an output section 100. The output section 100 is in a half-bridge structure, and more specifically, includes a high-voltage side transistor MH and a low-voltage side transistor ML. The high-voltage side transistor MH and the low-voltage side transistor ML include N-channel MOSFETs, respectively.

The short-circuit detection circuit 20 detects for a short circuit of the class D amplifier 10. More specifically, the short-circuit detection circuit 20 detects for a short circuit of the class D amplifier 10 based on a short-circuit current IshH flowing through the high-voltage side transistor MH or a short-circuit current IshL flowing through the low-voltage side transistor ML of the class D amplifier 10. The short-circuit detection circuit 20 of this embodiment includes a first voltage generation circuit 200, a first comparison circuit 220, a second voltage generation circuit 240 and a second comparison circuit 260.

Based on the short-circuit current IshL flowing through the low-voltage side transistor ML, the first voltage generation circuit 200 generates a voltage V1+ as a comparison target of a reference voltage Vref_sh. The first voltage generation circuit 200 of this embodiment primarily includes an OR circuit 202, a NOT circuit 204, transistors M11 to M16, transistors Q11 to Q13, resistors R11 to R14 and a switch S1.

The OR circuit 202 has a first input connected to a gate of the low-voltage side transistor ML, and a second input that is input with a test signal St1. The test signal St1 is normally fixed as low and becomes high during testing only. An output of the OR circuit 202 becomes high upon detecting the short-circuit current IshL of the low-voltage side transistor ML. The NOT circuit 204 is input with the output of the OR circuit 202.

The transistors M11 and M12 include N-channel MOSFETs. The transistor M11 has a drain connected to the output terminal 102 of the class D amplifier 10, a gate connected to the output of the OR circuit 202, and a source connected to a drain of the transistor M12. The transistor M12 has a gate connected to the output of the NOT circuit 204, and a source connected to ground.

The transistors Q11 to Q13 include NPN bipolar transistors. The transistors Q11 and Q12 form a pair of transistors of a current mirror circuit 206. The transistor Q13 has a base connected to a collector of the transistor Q11, an emitter connected to bases of the transistors Q11 and Q12, and a collector supplied with a voltage Vreg.

The resistors R11 and R12 have resistance values R, respectively. The resistor R11 has one end connected to ground, and the other end connected to an emitter of the transistor Q11, the source of the transistor M11 and the drain of the transistor M12. The resistor R12 has one end connected to ground, and the other end connected to an emitter of the transistor Q12.

The transistors M13 to M16 include P-channel MOSFETs. The transistor M13 and M14 form a pair of transistors of a current mirror circuit, and the transistors M15 and M16 form a pair of transistors of a current mirror circuit. The transistors M13 to M16 have sources supplied with the voltage Vreg. The transistor M13 has a drain connected to gates of the transistors M13 and M14 and is connected to a current source through which a current Iref_det flows. Moreover, the transistor M14 has a drain connected to a collector of the transistor Q11 and a base of the transistor Q13. Moreover, the transistor M15 has a drain connected to bases of the transistors M15 and M16 and a collector of the transistor Q12.

The resistor R13 and the resistor R14 form an element unit 208 (first element unit), the resistor R13 has a resistance value Rref1, and the resistor R14 has a resistance value Rref2. The resistor R13 has one end connected to a drain of the transistor M16 and the other end connected to the resistor R14. The resistor R14 has one end connected to ground and the other end connected to the resistor R13, and both ends connected to the switch S1.

The first comparison circuit 220 includes a comparator 222, an OR circuit 224, a filter 226, a buffer circuit 228 and a NOT circuit 230.

The comparator 222 compares the voltage V1+ generated by the first voltage generation circuit 200 with the reference voltage Vref_sh, and outputs a signal according to the comparison result. The OR circuit 224 is input with an output of the comparator 222 and an output of the OR circuit 202. The output of the OR circuit 224 passes through the filter 226 and each of the buffer circuit 228 and the NOT circuit 230, and is output as Vdet_OUT and Vdet_OUT_X.

Based on the short-circuit current IshH flowing through the high-voltage side transistor MH, the second voltage generation circuit 240 generates a voltage V2+ as a comparison target of the reference voltage Vref_sh. The second voltage generation circuit 240 of this embodiment primarily includes an OR circuit 242, a NOT circuit 244, a level shifter 246, transistors M21 to M27, transistors Q21 and Q22, resistors R21 to R24 and a switch S2.

The OR circuit 242 has a first input connected to a gate of the high-voltage side transistor MH, and a second input that is input with a test signal St2. The test signal St2 is normally fixed as low and becomes high during testing only. An output of the OR circuit 242 becomes high upon detecting the short-circuit current IshH of the high-voltage side transistor MH. The NOT circuit 244 is input with the output of the OR circuit 242. Moreover, the level shifter 246 is input with an output of the NOT circuit 244.

The transistor M21 includes an N-channel MOSFET, and the transistor M22 includes a P-channel MOSFET. The transistor M21 has a source connected to the output terminal 102 of the class D amplifier 10, a gate connected to the output of the NOT circuit 244, and a drain connected to a drain of the transistor M22. The transistor M22 has a gate connected to the output of the NOT circuit 204, and a source supplied with a voltage Vccp. The transistors Q21 and Q22 include PNP bipolar transistors. The transistors Q21 and Q22 form a pair of transistors of a current mirror circuit 248.

The resistors R21 and R22 have resistance values R, respectively. The resistor R21 has one end supplied with the voltage Vccp, and the other end connected to an emitter of the transistor Q21, the drain of the transistor M21 and the drain of the transistor M22. The resistor R22 has one end supplied with the voltage Vccp, and the other end connected to an emitter of the transistor Q22.

The transistors M23, M24 and M27 include N-channel MOSFETs. The transistors M25 and M26 include P-channel MOSFETs. The transistors M23 and M24 form a pair of transistors of a current mirror circuit, and the transistors M25 and M26 form a pair of transistors of a current mirror circuit.

The transistors M23 and M24 have sources connected to ground. The transistor M23 has a drain connected to gates of the transistors M23 and M24 and is connected to a current source through which a current Iref_det flows. Moreover, the transistor M24 has a drain connected to a drain and a gate of the transistor M25 and a gate of the transistor M26. Moreover, the transistor M25 has a source connected to a collector of the transistor Q21 and bases of the transistors Q21 and Q22. Moreover, the transistor M26 has a source connected to a collector of the transistor Q22 and a drain connected to a drain of the transistor M27.

The resistor R23 and the resistor R24 form an element unit 249 (first element unit), the resistor R23 has a resistance value Rref1, and the resistor R24 has a resistance value Rref2. The resistor R23 has one end connected to a source of the transistor M27 and the other end connected to the resistor R24. The resistor R24 has one end connected to ground and the other end connected to the resistor R23, and both ends connected to the switch S2.

The second comparison circuit 260 includes a comparator 262, an OR circuit 264, a filter 266, a buffer circuit 268 and a NOT circuit 270.

The comparator 262 compares the voltage V2+ generated by the second voltage generation circuit 240 with the reference voltage Vref_sh, and outputs a signal according to the comparison result. The OR circuit 264 is input with an output of the comparator 262 and an output of the level shifter 246. The output of the OR circuit 264 passes through the filter 266 and each of the buffer circuit 268 and the NOT circuit 270, and is output as Gdet_OUT and Gdet_OUT_X.

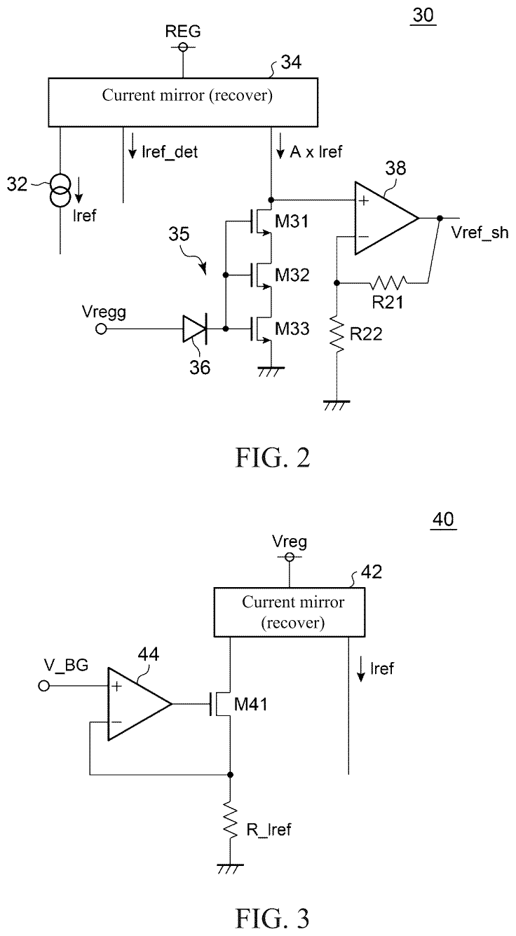

FIG. 2 shows a circuit diagram of a reference generation circuit 30 (reference generation unit) according to an embodiment of the present disclosure. The reference generation circuit 30 generates the current Iref_det and the reference voltage Vref_sh described with reference to FIG. 1. The reference generation circuit 30 includes a current source 32, a current mirror circuit 34, a diode 36, an operational amplifier 38, transistors M31 to M33, and resistors R21 and R22.

The current source 32 generates a reference current Iref of the current mirror circuit 34. The current mirror circuit 34 generates a current Iref_det that is set as A/C (A is a variable and C is a constant) times the reference current Iref. The current Iref_det serves as the current Iref_det described with reference to FIG. 1.

The transistors M31 to M33 form an element unit 35 (second element unit) and respectively include N-channel MOSFETs. The transistor M31 has a source connected to a drain of the transistor M32, and the transistor M32 has a source connected to a drain of the transistor M33. The transistor M31 has a drain connected to the current mirror circuit 34. The transistor M33 has a source connected to ground. The diode 36 is input with a voltage Vregg, and has an output supplied to gates of the transistors M31 to M33. In addition, in this embodiment, an example provided with three transistors M31 to M33 is described; however, the number of transistors can be two or less, or four or more.

The operational amplifier 38 has a positive input connected to the drain of the transistor M31, and a negative input connected between the resistors R21 and R22. A side opposite to the side where the resistor R21 and the resistor R22 are connected is connected to an output of the operational amplifier 38. Moreover, a side opposite to the side where the resistor R22 and the resistor R21 are connected is connected to ground.

The operational amplifier 38 uses a current (A*Iref) output from the current mirror circuit 34 to output the reference voltage Vref_sh. The reference voltage Vref_sh serves as the reference voltage Vref_sh described with reference to FIG. 1. Moreover, the reference voltage Vref_sh satisfies equation (1) below.

Vref_sh=A×B×Iref×Ron_ref (1)

Moreover, B is a constant determined by the resistance values of the resistors R21 and R22. Moreover, Ron_ref is an on-resistance of the transistors M31 to M33.

FIG. 3 shows a circuit diagram of a reference current circuit 40. The reference current circuit 40 generates the reference current Iref. The reference current Iref serves as the reference current Iref shown in FIG. 2. The reference current circuit 40 includes a current mirror circuit 42, an operational amplifier 44, a transistor M41 and a resistor R_Iref.

The transistor M41 includes an N-channel MOSFET. The transistor M41 has a drain connected to the current mirror circuit 42, a gate connected to an output of the operational amplifier 44, and a source connected to one end of the resistor R_Iref. Moreover, the resistor R_Iref has the other end connected to ground. The operational amplifier 44 has a positive input supplied with a voltage V_BG, and a negative input connected to a source of the transistor M41 and one end of the resistor R_Iref. If an input is provided to each of the operational amplifier 44 and the current mirror circuit 42, the reference current Iref is output from the current mirror circuit 42.

Operation details for detecting a short circuit of the class D amplifier circuit 1 of this embodiment are described below. For short-circuit detection, test signals St1 and St2 of the OR circuits 202 and 242 are switched from low to high. Next, a detection signal is output from the output terminal 102 to the output section 100. At this point in time, when the class D amplifier 10 contains a short circuit, a short-circuit current flows through the high-voltage side transistor MH or the low-voltage side transistor ML; however, an example in which the short-circuit current IshL flows through the low-voltage side transistor ML is described herein.

If the short-circuit current IshL flows through the low-voltage side transistor ML, the current mirror circuit 206 formed by the transistors Q11 and Q12 correspondingly operate, such that a collector current I1 (output current of the current mirror circuit 206) flows through the transistor Q12. Moreover, with the current mirror circuit formed by the transistors M15 and M16, a drain current I2 flows through the transistor M16. When a combined resistance of the resistors R13 and R14 is set as Rref, the positive input of the comparator 222 is input with a voltage V1+=I2*Rref. At this point in time, Rref is Rref1 when the switch S1 is on, and is Rref1+Rref2 when the switch S1 is off.

The comparator 222 compares the voltage V1+ with the reference voltage Vref_sh, and outputs a signal based on the result to the OR circuit 224. The OR circuit 224 outputs the signals Vdet_OUT and Vdet_OUT_X indicative of a detection result through the filter 226, the buffer circuit 228 and the NOT circuit 230. Accordingly, when the voltage V1+ is higher than the reference voltage Vref_sh, a short circuit in the class D amplifier 10 can be detected; when the voltage V1+ is lower than the reference voltage Vref_sh, it can be detected that the class D amplifier 10 does not contain any short circuit.

When a short circuit of the class D amplifier 10 is detected, equations (2) to (6) below are established.

I2×Rref=Vref_sh (2)

Vref_sh=A×B×Iref×Ron_ref (3)

I2=(A×B×Iref×Ron_ref)/Rref (4)

I2=4×I1 (5)

I1=(A×B×Iref×Ron_ref)/(4×Rref) (6)

Equation (7) is established regardless of whether there is a short circuit.

IshL×Ron+Vf1=I1×R+Vf2 (7)

Herein, Vf1 is a base-emitter voltage of the transistor Q11, and Vf2 is a base-emitter voltage of the transistor Q12. Moreover, Ron is an on-resistance of the low-voltage side transistor ML.

According to the above, regarding the short-circuit current IshL, equations (8) and (9) below are established.

IshL×Ron=((A×B×Iref×Ron)/(4×Rref))×R+Vf2−Vf1 (8)

IshL=((A×B×Iref×Ron_ref)/(4×Ron))×(R/Rref)+(Vt/Ron)×ln(B×C×Ron_ref)/(4×Rref) (9)

Moreover, Vt is a thermal voltage of the bipolar transistors forming the transistors Q11 and Q12.

In equation (9), values of Vt, Ron, Rref and Ron_ref are temperature dependent. Thus, the short-circuit current IshL is also temperature dependent. This embodiment is formed to use Ref to compensate for a temperature characteristic of the short-circuit current IshL. More specifically, the resistors R13 and R14 are formed such that a temperature characteristic of Rref is the same as a temperature characteristic of Ron_ref.

The second item on the right of equation (9) is Vf2−Vf1 on the right of equation (8), and is an item derived based on a diode equation. Since the item includes a ratio of Ron_ref to Rref, the temperature change in the short-circuit current IshL can be inhibited by Rref having a temperature characteristic the same as the temperature characteristic of Ron_ref. Accordingly, a short circuit of the class D amplifier 10 can be detected with good precision.

Moreover, a sign of the temperature characteristic of Rref is preferably the same as a sign of the temperature characteristic of Ron_ref. Accordingly, a temperature change in the short-circuit current IshL can be more reliably inhibited. Moreover, a slope of the temperature characteristic of Rref is preferably the same as a slope of the temperature characteristic of Ron_ref. Accordingly, the temperature change in the short-circuit current IshL can further be more reliably inhibited.

The sign of the temperature characteristic of Ron can be same as a sign of a temperature characteristic of the thermal voltage Vt of the transistors Q11 and Q12 forming a current mirror circuit 212. Accordingly, since the second item of equation (9) includes a ratio of Vt to Ron, the temperature change in the short-circuit current IshL can be inhibited. Moreover, a slope of the temperature characteristic of Ron can be the same as a slope of the temperature characteristic of Vt. Accordingly, the temperature change in the short-circuit current IshL can further be more reliably inhibited.

Moreover, a sign of a temperature characteristic of the resistance value R can be the same as the sign of the temperature characteristic of Rref. Accordingly, since the first item of equation (9) includes a ratio of R to Rref, the temperature change in the short-circuit current IshL can be inhibited. In addition, a slope of the temperature characteristic of R can be the same as the slope of the temperature characteristic of Rref. Accordingly, the temperature change in the short-circuit current IshL can further be more reliably inhibited.

Moreover, short-circuit detection that uses the short-circuit current IshH flowing through the high-voltage side transistor MH is performed similarly to short-circuit detection that uses the short-circuit current IshL flowing through the low-voltage side transistor ML. In this case, regarding equations (8) and (9), equations in which IshH substitutes for IshL are established, and the temperature change in the short-circuit current IshH can be inhibited by adjusting the on resistances Ron and Ron_ref of the high-voltage side transistor MH, the thermal voltages of the transistors Q21 and Q22, and the temperature characteristic of the combined resistance of the element unit 249.

### (Comparison Technique)

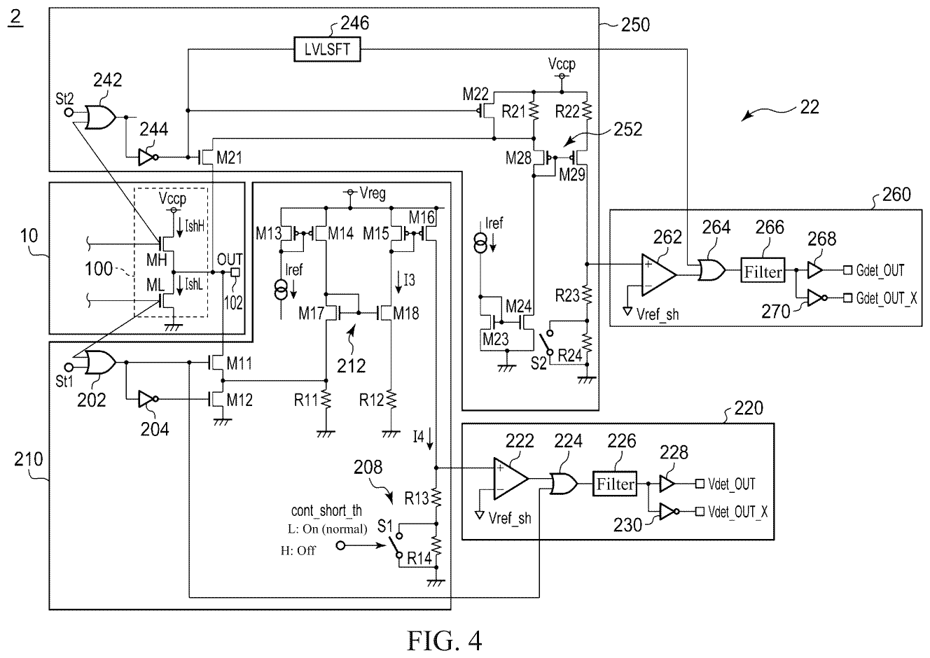

FIG. 4 shows a circuit diagram of a class D amplifier circuit 2 of a comparison technique. In FIG. 4, structures having substantially the same functions as those of the class D amplifier circuit 1 described with reference to FIG. 1 are represented by the same denotations, and repeated description is omitted as appropriate. The class D amplifier 2 of the comparison technique primarily differs from the class D amplifier circuit 1 of the embodiment in that, in the class D amplifier circuit 1 of the embodiment, the current mirror circuit formed by bipolar transistors includes MOSFETs.

The class D amplifier circuit 2 of the comparison technique includes a class D amplifier 10, a first voltage generation circuit 210, a first comparison circuit 220, a second voltage generation circuit 250 and a second comparison circuit 260.

The first voltage generation circuit 210 of the comparison technique includes a current mirror circuit 212 formed by a pair of transistors M17 and M18 including N-channel MOSFETs to substitute for the current mirror circuit 206 of the first voltage generation circuit 200 of the embodiment.

Equations (10) to (14) below are satisfied when short-circuit detection is performed based on the short-circuit current IshL flowing through the low-voltage side transistor ML of the class D amplifier 10.

I4×Rref=Vref_sh (10)

Vref_sh=A×B×Iref×Ron_ref (11)

I4=(A×B×Iref×Ron_ref)/Rref (12)

I4=4×I3 (13)

I3=(A×B×Iref×Ron_ref)/(4×Rref) (14)

I3 is a drain current of the transistor M18, and I4 is a drain current of the transistor M16.

Herein, equation (15) below is established regardless of whether there is a short circuit in the class D amplifier 10.

IshL×Ron+Vgs1=I3×R+Vgs2 (15)

Vgs1 is a gate-source voltage of the transistor M17, and Vgs2 is a gate-source voltage of the transistor M18.

According to the above, regarding the short-circuit current IshL, equations (16) and (18) below are established for the class D amplifier circuit 2 of the comparison technique.

IshL×Ron=((A×B×Iref×Ronref)/(4×Ron))×R+Vgs2−Vgs1 (16)

Ish=((A×B×Iref×Ron_ref)/(4×Ron))×(R/Rref)+Vgs1×\sqrt{ }((I3−I5)/I5)−Vth×\sqrt{ }((I5−I3)/I5) (17)

\sqrt{ }(I3)/\sqrt{ }(I5)=(Vgs2−Vth)/(Vgs1−Vth) (18)

Herein, Vth is a gate threshold voltage of the MOSFETs forming the transistors M17 and M18.

As shown in equation (17), temperature characteristics of Vgs1 and Vgs2 remain in the class D amplifier circuit 2 of the comparison technique, the item of Vgs1 (second item on the right) and the item of Vth (third item on the right) in the short-circuit current IshL. Thus, in the class D amplifier circuit 2 of the comparison technique, it is inevitable that short-circuit detection for the class D amplifier circuit 2 is affected from the temperature characteristics of Vgs1 and Vth.

In comparison, in the class D amplifier circuit 1 of the embodiment, since the current mirror circuit 206 is formed by bipolar transistors, the short-circuit current IshL is presented as shown by equation (9), and more particularly regarding the second item on the right, is presented by a ratio of Vt to Ron and a ratio of Ron_ref to Rref. Thus, by adjusting the temperature characteristics of Vt, Ron, Rref and Ron_ref, the temperature change in the short-circuit current IshL can be better inhibited in comparison with the class D amplifier circuit 2 of the comparison technique.

### <Simulation>

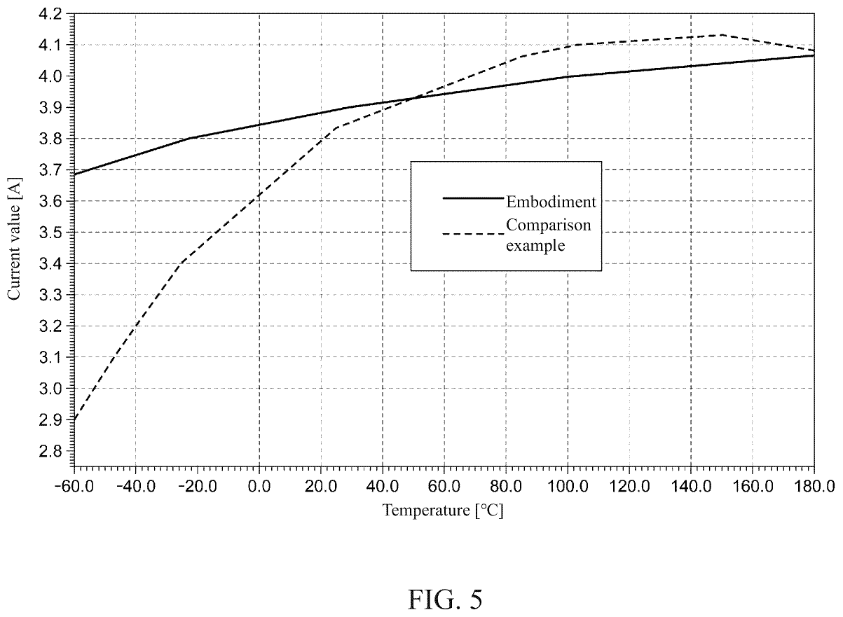

Simulation results of temperature characteristics of short-circuit currents for the class D amplifier circuit 1 in FIG. 1 and the class D amplifier circuit 2 in FIG. 4 are shown in FIG. 5. In FIG. 5, simulation results for the class D amplifier circuit 1 in FIG. 1 are represented by “embodiment”, and simulation results for the class D amplifier circuit 2 in FIG. 4 are represented by “comparison example”.

In the comparison example, within a temperature range between −60° C. and 180° C., the current value changes within a range between 2.9 A and 4.1 A. In comparison, in the embodiment, within the temperature range between −60° C. and 180° C., a change in the current value is inhibited to be within a range between 3.7 A and 4.0 A. Thus, the class D amplifier circuit according to the embodiment is capable of inhibiting a temperature change in the short-circuit current.

### (Conclusion)

In the recent years, amplifiers with higher efficiency are demanded, and amplifiers used have transferred from class A amplifiers or class B amplifiers to class D amplifiers. In order to detect a short circuit in an amplifier, detection for a short-circuit current within a specified range is performed. As an upper limit of the range is restricted, the upper limit needs to be, for example, below an upper limit of a fuse current of a wire and of an area of safety operating (ASO) of a switching element (for example, MOSFET) of an output section of a class D amplifier. Thus, if an output of the class D amplifier is increased, a lower limit of the detection range accordingly rises, resulting in a narrowed detection range.

As a method for expanding the detection range, the diameter of wires can be enlarged, or the number of wires can be increased. However, in the method above, costs are increased although the detection range can be expanded.

The class D amplifier circuit 1 according to this embodiment is capable of compensating for the temperature characteristic of the short-circuit current by the element unit 208. As a result, the precision for short-circuit detection of the class D amplifier 10 can be enhanced. Thus, even when a more costly method such as increasing the number of wires is not used, the class D amplifier 10 according to this embodiment still achieves the implementation of a product using a class D amplifier having a higher output.

### (Supplement)

Specific terms are used to describe the embodiments of the present disclosure; however, it is to be noted that the description provides examples for better understanding and is not to be construed as limitations to the present disclosure or the appended claims. The scope of the present disclosure is defined by the appended claims. Moreover, implementations, embodiments and variation examples not described herein are also encompassed within the scope of the present disclosure.

For example, the first element unit included in the class D amplifier circuit 1 may have an on-resistance of the MOSFET. In this case, the temperature change in the short-circuit current can be inhibited by adjusting the temperature characteristic of the on-resistance, thereby enhancing precision for short-circuit detection.

### [Notes]

An aspect of the techniques disclosed by the present application can be understood with reference to the description below.

### (Item 1)

A class D amplifier circuit, comprising:
a class D amplifier, including an output section that includes a switching element and outputs an output signal;
a current mirror circuit, including a pair of bipolar transistors configured to generate an output current according to a current flowing through the switching element;
an element unit, including a resistive component configured to generate a voltage based on the output current of the current mirror circuit; and
a comparator, configured to compare the voltage generated by the element unit with a reference voltage, wherein
the element unit is configured such that the resistive component compensates for a temperature characteristic of the current flowing through the switching element.

### (Item 2)

The class D amplifier circuit of Item 1, further comprising:
a reference generation unit including a second element unit having a resistive component when the element unit is set to be a first element unit, wherein the reference generation unit is configured to generate the reference voltage by passing a current through the second element unit, and
a sign of a temperature characteristic of the resistive component of the first element unit is same as a sign of a temperature characteristic of the resistive component of the second element unit.

### (Item 3)

The class D amplifier circuit of Item 2, wherein a slope of the temperature characteristic of the resistive component of the first element unit is same as a slope of the temperature characteristic of the resistive component of the second element unit.

### (Item 4)

The class D amplifier circuit of Item 2 or 3, wherein the second element unit includes a metal-oxide-semiconductor field-effect transistor (MOSFET), and the reference generation unit is configured to generate the reference voltage based on a voltage generated by an on-resistance of the MOSFET.

### (Item 5)

The class D amplifier circuit of any one of Items 1 to 4, wherein the switching element includes a MOSFET, and a sign of a temperature characteristic of an on-resistance of the MOSFET is same as a sign of a temperature characteristic of a thermal voltage of the bipolar transistor.

### (Item 6)

The class D amplifier circuit of Item 5, wherein a slope of the temperature characteristic of the on-resistance of the MOSFET is same as a slope of the temperature characteristic of the thermal voltage of the bipolar transistor.

1. A class D amplifier circuit, comprising:
a class D amplifier, including an output section that includes a switching element and outputs an output signal;
a current mirror circuit, including a pair of bipolar transistors configured to generate an output current according to a current flowing through the switching element;
an element unit, including a resistive component configured to generate a voltage based on the output current of the current mirror circuit; and
a comparator, configured to compare the voltage generated by the element unit with a reference voltage, wherein
the element unit is configured such that the resistive component compensates for a temperature characteristic of the current flowing through the switching element.

2. The class D amplifier circuit of claim 1, further comprising:
a reference generation unit including a second element unit having a resistive component when the element unit is set to be a first element unit, wherein the reference generation unit is configured to generate the reference voltage by passing a current through the second element unit, and
a sign of a temperature characteristic of the resistive component of the first element unit is same as a sign of a temperature characteristic of the resistive component of the second element unit.

3. The class D amplifier circuit of claim 2, wherein
a slope of the temperature characteristic of the resistive component of the first element unit is same as a slope of the temperature characteristic of the resistive component of the second element unit.

4. The class D amplifier circuit of claim 2, wherein
the second element unit includes a metal-oxide-semiconductor field-effect transistor (MOSFET), and
the reference generation unit is configured to generate the reference voltage based on a voltage generated by an on-resistance of the MOSFET.

5. The class D amplifier circuit of claim 1, wherein
the switching element includes a MOSFET, and
a sign of a temperature characteristic of an on-resistance of the MOSFET is same as a sign of a temperature characteristic of a thermal voltage of the bipolar transistor.

6. The class D amplifier circuit of claim 5, wherein
a slope of the temperature characteristic of the on-resistance of the MOSFET is same as a slope of the temperature characteristic of the thermal voltage of the bipolar transistor.
